(19) United States
(12) Patent Application Publication
(10) Pub. No.: US 2025/0194331 A1
(43) Pub. Date: Jun. 12, 2025

(54) OPTOELECTRONIC ARRANGEMENT AND METHOD OF PROCESSING

(71) Applicant: ams-OSRM International GmbH, Regensburg (DE)

(72) Inventor: Christoph Klemp, Regensburg (DE)

(21) Appl. No.: 18/846,122

(22) PCT Filed: Mar. 17, 2022
(86) PCT No.: PCT/EP2022/056988

§ 371 Date: Sep. 11, 2024

(51) Int. Cl. H10H 29/85; H10H 20/819; H10H 29/01

(52) U.S. Cl. CPC H10H 29/857; H10H 20/819; H10H 29/0364

(57) ABSTRACT

In an embodiment an optoelectronic arrangement includes a carrier, at least one optoelectronic device configured to emit light through at least one emission surface and including at least one side edge and a center with a rotational axis substantially perpendicular to the at least one emission surface, and a breakable anchoring structure coupling the at least one optoelectronic device to the carrier on a surface facing away the at least one emission surface and including a first main surface that is at least partially attached to the at least one optoelectronic device, wherein the first main surface is displaced with respect to the center and includes a corner facing the center with a smallest distance to it, and wherein the first main surface comprises a triangular shape with an angle at the corner of less than 60° or wherein the first main surface comprises a non-rectangular shape that is symmetrical along an axis through the corner and the center.

### CROSS-REFERENCE TO RELATED APPLICATIONS

This patent application is a national phase filing under section 371 of PCT/EP2022/056988, filed Mar. 17, 2022, which is incorporated herein by reference in its entirety.

### TECHNICAL FIELD

The present invention concerns an optoelectronic arrangement and a method of processing the same.

### BACKGROUND

μLEDs and other small semiconductor components are often manufactured on a wafer level in such way that they can be picked up by a respective tool (i.e. stamp pad) and subsequently placed onto a final or temporary carrier. For this purpose, the components may be processed by applying a structured sacrificial layer on the component's surface into which anchoring posts are generated attached to the component via an interface. The anchoring structure can be bonded to a temporary wafer together with the sacrificial layer.

The resulting structure provides re-bonding the component thus enabling further processing of the components surface opposite to the anchoring posts. When ready, the sacrificial layer is removed, leaving the anchoring post behind on which the component is resting upon.

The processing of the anchoring post for such components provides various challenged. For once the semiconductor components and particularly so called μ-LEDs are becoming smaller and smaller in size approaching a few 10 μm in length or even smaller. This shrinking process most likely causes a shrinking of the post's diameter as well, reducing the mechanical stability. While a smaller interface is not necessarily disadvantageous, as it also reduces the adhesive force of the interface, the adhesive force may also inherit a higher unpredictability or larger tolerances. In addition, smaller structures are affected to a higher extend by the existing processing tolerances, a circumstance increasing with the material usually used for such anchoring posts. Changing the material of the post may reduce this issue, but other challenges remain.

### SUMMARY

Embodiments provide more reliable anchoring posts for large devices as well as smaller optoelectronic devices like μLEDs.

The inventor proposes a new setup for processing and positioning the anchoring posts used as a temporary rest for optoelectronic devices in particular or more generally semiconductor devices. The proposed solution enables the devices to be picked up and placed with a larger process window, such that pre-processed wafers with the devices can be shipped and processed at the customer's site.

In addition, the anchoring posts may be used to provide electrical conductivity for testing the devices prior to the actual picking process or also during the picking and placing process. In some instances, it makes use of the electrical field generated by the anchoring structure. The anchoring structure can be used for a plurality of semiconductor devices.

In some aspects, an optoelectronic arrangement is proposed comprising a carrier and at least one optoelectronic device. The at least one optoelectronic device is configured to emit light through at least one emission surface and further comprises at least one side edge and a centre. The centre corresponds to the middle of the device and forms a rotational centre point for some shapes with a rotational axis substantially perpendicular to said at least one emission surface. A breakable anchoring structure is coupling the at least one optoelectronic device to the carrier. For this purpose, the breakable anchoring structure is attached with a first main surface to a side of the at least one optoelectronic device facing away the at least one emission surface. In accordance with the proposed principle, the first main surface is displaced with regards to the centre and comprises a corner facing the centre, wherein said corner is the closest point of the anchoring structure towards the centre. In other words, the smallest dimension of the main surface of the breakable anchoring structure is pointing towards the centre.

The displacement of the breakable anchoring structure will cause a highly-effective “leverage torsional force” or torque during picking the optoelectronic device, which is not available if the breakable anchoring structure is not displaced or located below the centre of the device. In addition to the torque being generated, the corner of the main surface facing the centre will minimize “initial breakaway torque”. The combination of these two aspects provides a more predictable but also smaller force when picking up the device compared to the actual size of the interface.

The lateral displacement (i.e. moving the corner closer or further away from the centre) allow adjusting the initial torque and the torque during the picking procedure. The area of the interface between the main surface and the at least one optoelectronic device can also be adjusted and will therefore provide adjustability for the adhesion force. This will allow to set a relatively high adhesion providing good transport or handling properties, while enabling a very low initial torque for picking. In other words, the proposed principle ensures an easy and low force picking while preventing accidental breaking or rupture of the interface. The low initial torque also prevents residues or cracks in the device during the picking process thus reducing the probability of transfer damages.

The size of the interface and its material are also parameters easily adjustable and affecting the behaviour. However, the combination of size and displacement generally leads to larger interface sizes, which are easier to process and to structure during processing of the device.

In this regard, the expression “corner” should not be considered in a strict mathematical sense, but corresponds to an area in which two edges of the main surface actually meet. The corner shall therefore comprise the smallest diameter of the main surface and/or the interface. The corner may be relatively sharp, to the extent possible for the respective manufacturing process, but can also be deliberately formed with a round shape.

In some instances, the main surface extends at least partially beyond the at least one side edge. In other words, the breakable anchoring structure will extend below a mesa structure (or more precisely the opening caused by a mesa etching process) and into the space separating two or more devices from each other. However, it also allows larger shapes for the breakable anchoring structure, enlarging the process window for its structure and manufacturing process. In some further aspects, the at least one side edge comprises a corner element with the first main surface attached to said corner element. Thus, the breakable anchoring structure may extend over a corner element of the at least one optoelectronic device. The optoelectronic device may comprise a non-round shape, but a polygon (rectangular or hexagonal shape for example).

To prevent an unpredictable or undesirable variation of the torque during the picking procedure, the shape and the position of the breakable anchoring structure can be adjusted accordingly. In some aspects, the corner of the main surface of the breakable anchoring structure rests on a virtual axis through the centre of the optoelectronic device. The virtual axis corresponds in this regard to a symmetrical axis for the breakable anchoring structure and/or the first main surface.

In some other instances, the first main surface comprises a triangular shape. This shape can be for example an isosceles triangle with an angle at the corner of no more than 60°. An angle of 60° corresponds to an equilateral triangle, but the angle may also be less than 60°, for example 50° or 45° or even 40°. In some instances, the first main surface comprises a non-rectangular shape that is symmetrical along an axis through the corner and the centre. In some other instances, a virtual axis through the centre and the corner can be drawn, which may be perpendicular onto a side edge of the device or that may also cut through a corner edge of the at least one optoelectronic device.

The material of the breakable anchoring structure is adjustable. In some instances, the breakable anchoring structure comprises a metal or an alloy. In some further instances, the breakable anchoring structure may comprise a metal stack, a conductive oxide or a doped semiconductor. In some other instances, an insulating material is used, i.e. AlN or SiO₂ or BCB. In some further instances, the interface may actually comprise a different material. For example the interface may comprise some metal (i.e. a thin metal layer on the main surface of the breakable anchoring structure), while the core of the breakable anchoring structure is of a dielectric material or a semiconductor material.

In useful embodiments, the material chosen for the breakable anchoring structure should be different from a material used for a potential sacrificial layer to prevent an undesired etching. More particularly, the material chosen for the breakable anchoring structure should be substantially inert against the etchant used to etch a possible sacrificial layer surrounding the breakable anchoring structure.

Some aspects concern the structure of the at least one optoelectronic device and more particular the location and position of the interface of the breakable anchoring structure on the device's surface. In some instances, the optoelectronic device is a vertical LED or μ-LED with its two contacts on opposing sides. The at least one optoelectronic device may comprise a contact portion and a surface portion surrounding the contact portion. In some instances, the contact portion stands out over the surrounding portion. Hence, the surface portion surrounding the contact portion is recessed. In accordance with some aspects of the proposed principle, the corner of the main surface is located on the surface portion. This will allow to provide an attachment of the anchor structure onto the optoelectronic device without any interference on the contact portion itself. For example, possible residues affecting the contact portion are omitted.

In some other aspects, the at least one optoelectronic device comprises an inclined sidewall and the first main surface is located at least partially on said inclined sidewall. In this regard, the first main surface may extend from the bottom surface (next to the contact portion of the optoelectronic device) onto the inclined sidewall. In some other instances, the first main surface is located on the inclined sidewall up to the edge of the device. The breakable anchoring structure is thus located within the mesa structure. In some further aspects, a specific interface layer is provided between the first main surface and the at least one optoelectronic device. In a further alternative, the first main surface may be formed by an interface layer attached to the at least one optoelectronic device, the interface layer optionally comprising a dielectric material.

The breakable anchoring structure comprises in some aspects a larger cross-sectional area than the area of the first main surface at a distance into the direction to the carrier. In other words, the breakable anchoring structure is characterized by a cross-sectional area that may increase with an increasing distance from the interface or the optoelectronic device.

Some further aspects concern more than a single optoelectronic device. The breakable anchoring structure is implemented in certain shapes allowing the attachment of several device thereto. In some instance, the proposed optoelectronic arrangement further comprises a second optoelectronic device that is separated from the at least one optoelectronic device by a mesa structure. The second optoelectronic device comprises at least one side edge and a centre, in particular a rotational centre with a rotational axis substantially perpendicular to the emission surface of the second optoelectronic device. The breakable anchoring structure now includes a second main surface that is at least partially attached to the second optoelectronic device. Like for the first main surface the second main surface is displaced with regards to the centre and comprises a corner facing the centre of the second optoelectronic device with the lowest distance to it.

In this regard, the breakable anchoring structure comprises a 120° or a 180° rotational symmetry around its centre point. Such 120° rotational symmetry corresponds to a three-pointed star structure, in which each prong of the star form one of the respective main surface. For a 180° rotational symmetry, the breakable anchoring structure may comprise 2 or 4 such prongs. Other symmetries like 90° are also possible resulting in an n-pointed star with n respective prongs forming the main surfaces and n being a number in particular from 1 to 4.

Another aspect concerns a method of processing an optoelectronic device. For this purpose, a growth substrate is provided with a semiconductor layer stack, the layer stack comprising an active region. The semiconductor layer stack is optionally mesa structured as to form a plurality of distinct optoelectronic devices, each of the plurality of distinct devices comprising a centre as defined above. A temporary carrier with a breakable anchoring structure is provided. The breakable anchoring structure comprises a first main surface to which a first one of the plurality of optoelectronic devices is attached to from a side opposite a main emission surface. The first main surface is displaced with regards to the centre and comprises a corner facing the centre with the lowest distance to it.

Processing of the breakable anchoring structure can be performed by various means. For example, after structuring the semiconductor layer stack, material of a sacrificial layer can be applied onto the surface of the layer stack. The sacrificial layer comprises recesses giving access to the devices' surface. Material of the breakable anchoring structure is filled into the recesses. After re-rebonding the layer stack to a temporary carrier, the sacrificial layer is removed, leaving the breakable anchoring structure behind.

In some instances, the breakable anchoring structure comprises a second main surface that is at least partially attached to a second one of the plurality of optoelectronic devices. The second main surface is displaced with regards to the centre and comprises a corner facing a centre of the second optoelectronic device with the lowest distance to it. The breakable anchoring structure can have different shapes that a formed during structuring of the sacrificial layer.

Generating a temporary carrier may comprise in some instances the formation of a breakable anchoring structure with the first main surface comprising a triangular shape in particular a isosceles triangle with an angle at the corner of less than 60°. Generally, the breakable anchoring structure can be structured with the first main surface comprising a non-rectangular shape that is symmetrical along an axis through the corner and the centre. The symmetry provides the above-mentioned advantages.

For attaching more than a single optoelectronic device to the breakable anchoring structure, an n-pointed, in particular a three-pointed star with the prongs forming respective main surfaces therefrom is structured on the top surface of adjacent devices. In some instances, material of a sacrificial layer is applied to the structured surface of the optoelectronic devices with recesses in the sacrificial layer with a shape and at positions corresponding to the breakable anchoring structure. The recesses are filled with the material of the breakable anchoring structure. In some instances the material comprises a metal or a conductive material thus allowing the breakable anchoring structure to be used for electrical testing. Alternatively the material of the breakable anchoring structure is a dielectric material, a BCB for example. It is however different from material used for the sacrificial layer and should also not be affected by an etchant used to remove the sacrificial layer material.

When picking the optoelectronic devices, the location of the break of the optoelectronic device from the first main surface begins at the position of the corner and continues from there in the direction of one side edge of the optoelectronic device. Thus, the overall force used for breaking and picking is smaller than with different shape and also more predictable.

### BRIEF DESCRIPTION OF THE DRAWINGS

Further aspects and embodiments in accordance with the proposed principle will become apparent in relation to the various embodiments and examples described in detail in connection with the accompanying drawings in which

FIGS. 1A and 1B illustrate a schematic cross-section through an optoelectronic arrangement with some aspects of the proposed principle;

FIGS. 2A to 2F show several shapes of a main surface of a breakable anchoring structure with some aspects of the proposed principle;

FIG. 3 shows a cut view of an optoelectronic arrangement according to some aspects of the proposed principle;

FIG. 4 illustrates a cut view of another optoelectronic arrangement in accordance with some aspects of the proposed principle;

FIG. 5 shows a cut view of a third embodiment of an optoelectronic arrangement in accordance with some aspects of the proposed principle;

FIG. 6 shows an arrangement of several optoelectronic devices with a breakable anchoring structure in accordance with some aspects of the proposed principle; and

FIG. 7 shows the cut view through the arrangement of FIG. 6.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the Figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual Figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the Figures. So it is possible to deduce such relations between the elements based on the Figures.

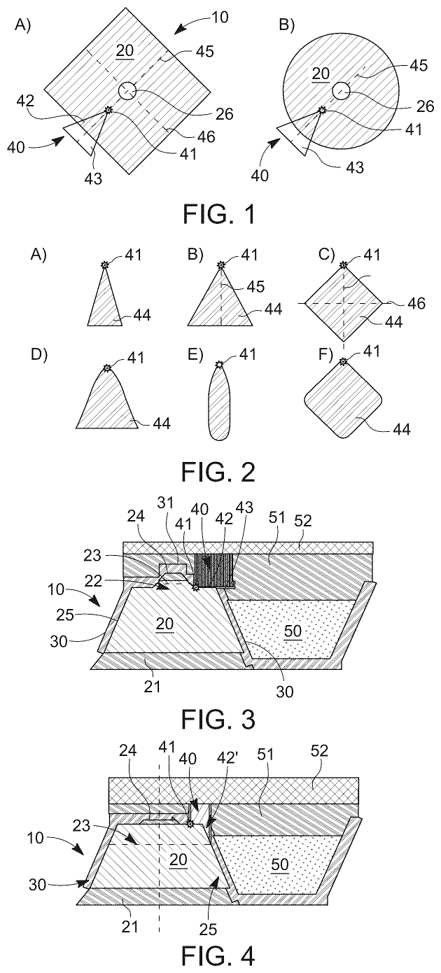

FIGS. 1A and 1B illustrate schematic cross sections through two different optoelectronic arrangements showing some aspects of the proposed principle.

In FIG. 1A the optoelectronic arrangement comprises a substantially rectangular optoelectronic device 20 having its centre point 26 in the middle of the device. The centre point 26 lies in the cross section of the two axes 45 and 46 cutting the respective optoelectronic device 20 into four quarters of similar or substantially same size. Each of the axes is substantially perpendicular onto opposing edges of the device. Consequently, the centre 26 is defined as the crossing point for the two axes 45 and 46. The optoelectronic device also comprises an active region configured to emit light. The schematic cross-section illustrated in this embodiment corresponds to the bottom of the respective optoelectronic device 20; that is that light mainly exits the optoelectronic device out of the other plane and not out of the plane currently illustrated.

The optoelectronic arrangement of FIG. 1A further comprises a breakable anchoring structure 40. The breakable anchoring structure 14 includes a main surface 43 in the shape of an isosceles triangle. The top corner 41 of the isosceles triangle faces as the centre 26 and particularly lies on the virtual axes 45 through the centre point 26. Said axis also cuts the main surface of the breakable anchoring structure into two halves of substantially equal proportions. The portion of the main surface 43 overlapping onto the surface of the optoelectronic device is defined as interface 42, which attaches the optoelectronic device to the breakable anchoring structure and subsequently connects it with a temporary carrier. Consequently, the optoelectronic device 20 rests on the interface of 42.

FIG. 1B illustrates a further example of an optoelectronic arrangement in accordance with the proposed principle. In this embodiment, the optoelectronic device 20 comprises a circular shape, having its centre 26 in the middle. Like in the previous example, the top corner 41 of the breakable anchoring structure faces centre 26 and rests on a line 45 through centre 26. Said line 45 also acts as a symmetry axis through the breakable anchoring structure onto which the halves of the breakable anchoring structure can be mirrored upon. The top corner 41 comprises the smallest diameter of the overall interface attached to the optoelectronic device and is displaced with respect to the centre point 26.

When picking the optoelectronic device during a transfer process, the eccentric lateral position of interface 42 will create a highly effective leverage torsional force. This torsional force starts at the smallest dimension of the interface 42, which corresponds to the corner 41 in the direction of centre 26.

The corner will act as an initial break-away point with only a small force necessary to initiate the breaking. The breaking (that is the separating of the interface from the surface of the optoelectronic device) then continues towards the inverted side 44 of the respective main surface until interface 42 is completely separated from the surface of the optoelectronic device.

Due to the shape of the breakable anchoring structure and particular interface 42, the overall initial force required to pick up the optoelectronic device is more predictable. It follows a certain force distribution function starting from a very low force to initiate the breaking followed by a slightly increasing force due to the increasing area of the interface 42, until interface 42 is completely separated. When comparing the two embodiments in FIGS. 1A and 1B, one may note that the area of the interface (overlapping area of main surface and the surface of the optoelectronic device) in FIG. 1A is continuously increasing with an increasing distance from centre 26. In FIG. 1B however, the area is decreasing at some distance from the centre, because of the round shape of the optoelectronic device's surface. This will result in a smooth increase of the force to a maximum and then a decrease again avoiding sudden rip-offs.

In contrast to conventional procedures, in which the interface lies virtually over the centre 26, the proposed approach provides a lower overall torque necessary for picking and separating the optoelectronic device. At the same time, a smaller but still a moderate adhesion of the interface 42 is present, allowing a more robust handling for example for shipping after removal of the sacrificial layer. In addition, the overall size of the interface of 42 can be increased without an increased risk of residuals on the device's surface due when picking and separating the device. This will simplify the overall fabrication process and structuring process for the breakable anchoring structures.

The applied torque also reduces the overall residuals or particles that are being left on the surface. Damages or cracks on the optoelectronic device generated by variations of the force used for picking in conventional devices would be largely omitted, since the initial breakaway 30 starts at the very low force that is easily controllable.

The shape of the breakable anchoring structure can be adjusted to fit respective needs of the shape and the size of the optoelectronic devices to be picked and transferred. Consequently, adjusting the shape as well as the size of interface 42 together with the overall size of the main surface and the material of the interface will provide a set of separately and individually adjustable parameters, which can be set to fit the desired needs. FIGS. 2A to 2F illustrate some examples of various forms and shapes of main surfaces of such breakable anchoring structures.

FIG. 2A shows an isosceles triangle having its anchoring point 41 at the top corner of the respective triangle. This is the corner that also comprises the smallest angle particularly smaller than 60°. A smaller angle usually results in a sharp corner, which will reduce the initial breakaway force. The increase of the force necessary to separate the interface is depending of said angle at the top corner.

FIG. 2B illustrates an alternative embodiment of the main surface of the breakable anchoring structure of FIG. 2A, in which the triangle is formed as an equilateral triangle with equal length of their respective sizes. As a result, the top corner 41 includes an angle of 60°. Such main surface might be useful as it comprises a rotational symmetry by 120°, allowing the other corners of the respective triangle to be placed as portions of interfaces on adjacent semiconductor structures. FIG. 6 explained further below in detail provides an example similar to the structure of FIG. 2B.

FIG. 2D illustrates a further example, in which the top corner 41 is deliberately formed with a round shape, that is easier to manufacture and structure. In fact, corners 41 usually reflect a slightly around shape due to the used structuring and etching processes. Nevertheless, the corners of 41 are characterized by the smallest diameter of the respective interface 42 and directed towards the centre of the optoelectronic device. The other side 44 is structured differently in this example.

FIGS. 2C and 2F illustrate another example, in which the main surface of the breakable anchoring structures is implemented as a rectangle. One of the corners forms the interface top corner 41. In FIG. 2F, the top corner 41 is slightly rounded but still comprises the smallest diameter on the interface. While in the previous embodiments with the triangles the symmetrical axis runs through the corner 41 and only provides a mirror symmetry, the respective axes 45 and 46 in FIG. 2C and 2F allow for a rotational symmetry as well as mirroring symmetry by 90°. Similar to the embodiment of FIG. 6, the respective main surfaces provide a possibility to combine a plurality of optoelectronic devices on a single breakable anchoring structure.

FIG. 2B illustrates a further example with an ellipsoidal main surface, with a decreasing diameter towards corner 41 of the main surface anchoring structure. As illustrated the breakable anchoring structures can have the various shapes each of those being particularly useful for various optoelectronic devices.

As already mentioned above, the breakable anchoring structure is displaced onto the surface portion of the device with respect to its respective centre point to obtain the necessary initial torque for separating the surface of the device from the interface during the picking procedure.

FIG. 3 illustrates a cut view of an example of an optoelectronic arrangement 10 in accordance with some aspects of the proposed principle. The optoelectronic arrangement comprises an optoelectronic device 20 with a light emission surface on the bottom. The device also comprises two doped regions 22 and an active region 23 arranged between the two differently doped regions. A contact portion 24 is applied on to one of the doped regions and contact region 21 on the other doped region. Contact region 21 also acts as a light emission surface.

As shown in the embodiment of FIG. 3, the semiconductor material of optoelectronic device 20 comprises an inclined sidewall 25 with a decreasing diameter towards the top contact portion 24. Top contact portion 24 is made of metal or other conductive material used for current injection. The other contact 21 acting as main emission surface 21 comprises a transparent conductive material for carrier injection. During the manufacture of the optoelectronic device 20, mesa structure 50 is being generated separating the optoelectronic device 20 from another device adjacent to it. The surface of the inclined sidewalls as well as the surface of the top contact 24 is covered by the sacrificial layers 30 and 31, respectively.

In accordance with the present invention, a portion of the sacrificial layer 30 is removed, such that a portion of the surface of the optoelectronic device 20 is exposed. Material of a breakable anchoring structure 40 is filled into the recess. The breakable structure 40 is attached to the surface of device 20 forming an interface 42 on its main surface 43. The closest part of said interface towards a centre of the device 20 is defined as corner 41. Corner 41 faces the centre of the optoelectronic device. As shown in FIG. 3, the interface 42 is below the active region, that is the interface is closer to contact 21 than the active region. This is a manufacture design choice and can be adjusted to fit the respective needs. The sidewall of the device adjacent to the active region may be covered by a small Al₂O₃ or another dielectric layer to reduce crystal defects and non-radiative recombination centres. Said dielectric layer may also form the top layer of the surface and thus part of interface 42.

A pattern resist 51 covers and surrounds the sacrificial layer 30 as well as the material of the breakable anchoring structure 40. Pattern resist 51 is bonded to a temporary carrier 52. After removal of the sacrificial layer 30, the optoelectronic device 20 rests on the interface 42 being attached to the breakable anchoring structure 40.

FIG. 4 illustrates an alternative embodiment of the optoelectronic arrangement in accordance with some aspects of the proposed principle.

The optoelectronic device 20 of the arrangement comprises an active region 23, which is located below the interface 42′ of the breakable anchoring structure 40. This will provide another protection of the active region during the separation of the breakable anchoring structure from the optoelectronic device. The transfer process ensures that the interface of the breakable anchoring structure does not interfere with the active region. The optoelectronic device 20 further comprises a contact portion 24 arranged on the surface of the optoelectronic device. Still, the top contact portion is distanced from the interface to avoid any residues being left on the top contact portions.

The breakable anchoring structure 40 comprises the corner 41 being processed such that it faces the centre of the optoelectronic device. The interface 42 extends from the top surface of the optoelectronic device starting corner 41 to a portion of the sidewalls 25 of the respective device. In other words, the main surface of breakable anchoring structure 40 extends at least partially on the sidewalls of the optoelectronic device. The pattern resist 51 fills in the gaps between the sacrificial layer 30, the breakable anchoring structure 40 and the temporary carrier 52. The breakable anchoring structure 40 is attached to the temporary carrier 52 like in the previous embodiment of FIG. 3.

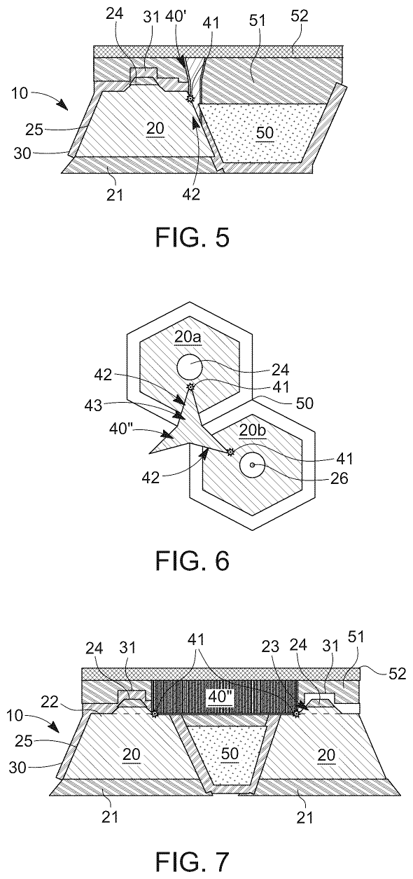

In the two previous embodiments, the breakable anchoring structure does not change its diameter with an increasing distance from the interface. FIG. 5 illustrates another embodiment, in which the breakable anchoring structure 40 comprises an increasing diameter with increasing distance from the respective interface. The present embodiment, interface 42 arranged only on the sidewall 25 of the device. Similar to the previous embodiment, corner 41 of the main surface and interface 42 is directed to the centre of the optoelectronic device. In the present embodiment, the breakable anchoring structure 40 extends from the sidewalls 25 of the optoelectronic device towards the temporary carrier. The upper portion of the breakable anchoring structure comprises an increasing diameter to provide an improved stability after the sacrificial layer 30 is removed.

As shown in the previous embodiments, the optoelectronic device is usually surrounded by a mesa structure 50 separating one device from a respective second device. During processing the devices on wafer level, the mesa structure 50 allows separating the various optoelectronic devices from each other, which then can subsequently be attached to a breakable anchoring structure 40. Such approach is particularly useful when the respective optoelectronic devices comprise symmetric and periodic shapes. Such shapes include a hexagonal form, a quadrature form and the like.

FIG. 6 illustrates an embodiment for breakable anchoring structure 14″, which is attached to a plurality of the respective optoelectronic devices 20a and 20b. In this embodiment, the breakable anchoring structure 40″ is formed as a three-pointed star, wherein each of its prongs forms one of the main surfaces. Those main surfaces are attached to the processed optoelectronic devices. In the present example, a first prong forms the first main surface that is attached to the top surface of the first optoelectronic device 20a on interface 42. A second prong forms a second main surface and is attached to a second device 20b. The areas 43 of both prongs not being part of interface 42 merge into a common column in the centre of anchoring post 40″, which is attached to the temporary carrier.

Both devices 20a and 20b are formed with a hexagonal shape, wherein a corner of its respective side edges is attached to the interface of the first and second main surface, respectively.

Arranging the main surface over a corner of the respective optoelectronic device further changes the necessary force applied during the picking sequence. As previously disclosed the picking torque starts with a very low initial breakaway force due to corner 41 closest to the centre and then increases with the increasing interface area. At some distance, the interface area, i.e. the overlapping area of main surface of structure 40 and surface of device 20 decreases again because of the edge corner of the device's shape. Consequently, the force necessary to further separate the device from the interface starts decreasing again when the actual interface size becomes smaller.

The present embodiment provides three-pointed breakable structure to be attached to three adjacent optoelectronic devices. The structure of the optoelectronic devices and the breakable anchoring structure results in a 3:1 ratio, in which one breakable anchoring structure supports three optoelectronic devices. The size of the Mesa structure 50 in between is adjusted in such way that the optoelectronic device can be individually separated and picked up from the breakable anchoring structure without affecting the other optoelectronic devices attached thereto.

FIG. 7 illustrates an embodiment in cross-section of the structure of FIG. 6. The breakable anchoring structure 40 extends across a portion of the Mesa structure 50 and provides an interface with the corner 41, to which the optoelectronic devices 20 are attached to. The material of the breakable anchoring structure is different from the material used for the sacrificial layer. For example, the material of the anchoring structure is a metallic conductive material, while the sacrificial layer consists of SiO₂ or any other dielectric material to be used as a sacrificial layer. In this regard, the interface between the breakable anchoring post and the surface of the respective optoelectronic device may contain an additional layer of the material being a different from the surface material of the optoelectronic device as well as from the material in the core of the breakable anchoring structure. For example, metallic or conductive layer can be used in case, possible residual leftovers will not cause a short circuit. As an alternative the material for the breakable anchoring structure can include Al₂O_{3,} AlN, BB, ITO or certain alloys, all of which are basically inert versus the etchant for the sacrificial layer.

In some aspects, the breakable interfaces structure may comprise a metal, which allows for current injection into the device for testing purposes. This will enable testing the respective optoelectronic devices before or during the separation process in order to ensure only a functional devices to be fully transferred. In some other aspects, the material is a dielectric thus not affecting any electrical characteristics and avoiding possible shorts due to conductive residuals.

1.-18. (canceled)

19. An optoelectronic arrangement comprising:
a carrier;
at least one optoelectronic device configured to emit light through at least one emission surface, the at least one optoelectronic device comprising at least one side edge and a center with a rotational axis substantially perpendicular to the at least one emission surface; and
a breakable anchoring structure coupling the at least one optoelectronic device to the carrier on a surface facing away the at least one emission surface, the breakable anchoring structure comprising a first main surface that is at least partially attached to the at least one optoelectronic device,
wherein the first main surface is displaced with respect to the center and comprises a corner facing the center with a smallest distance to it, and
wherein the first main surface comprises a triangular shape with an angle at the corner of less than 60°, or
wherein the first main surface comprises a non-rectangular shape that is symmetrical along an axis through the corner and the center.

20. The optoelectronic arrangement according to claim 19, wherein the first main surface at least partially extends beyond the at least one side edge.

21. The optoelectronic arrangement according to claim 19, wherein the at least one side edge comprises a corner element with the first main surface attached to the corner element.

22. The optoelectronic arrangement according to claim 19, wherein the corner rests on a virtual axis through the center, the virtual axis corresponding to the symmetrical axis for the breakable anchoring structure and/or the first main surface.

23. The optoelectronic arrangement according to claim 19, wherein the breakable anchoring structure comprises at least one of the following materials: a metal or an alloy, a metal stack, a conductive oxide, a doped semiconductor, a dielectric material, or a BCB (Bisbenzocyclotene).

24. The optoelectronic arrangement according to claim 19, wherein the at least one optoelectronic device comprises a contact portion and a surface portion surrounding the contact portion and optionally recessed with respect to the surface portion, and wherein the corner is located on the surface portion.

25. The optoelectronic arrangement according to claim 19, wherein the at least one optoelectronic device comprises an inclined sidewall and the first main surface is located at least partially on the inclined sidewall.

26. The optoelectronic arrangement according claim 19, further comprising an interface layer between the first main surface and the at least one optoelectronic device, or wherein the first main surface is formed by an interface layer attached to the at least one optoelectronic device, the interface layer optionally comprising a dielectric material.

27. The optoelectronic arrangement according to claim 19, wherein the breakable anchoring structure comprises a larger cross-sectional area than an area of the first main surface at distance towards the carrier.

28. The optoelectronic arrangement according to claim 19, further comprising:
a second optoelectronic device that is separated from the at least one optoelectronic device by a mesa structure, the second optoelectronic device comprising at least one side edge and a center with a rotational axis substantially perpendicular to the at least one emission surface,
wherein the breakable anchoring structure comprises a second main surface that is at least partially attached to the second optoelectronic device, and
wherein the second main surface is displaced with respect to the center and comprises a corner facing the center of the second optoelectronic device with the smallest distance to it.

29. The optoelectronic arrangement according to claim 19, wherein the anchoring structure comprises a 120° rotational symmetry or a 180° rotational symmetry around its center point.

30. The optoelectronic arrangement according to claim 19, wherein the anchoring structure forms an n-pointed star with prongs forming respective main surfaces therefrom.

31. A method for processing the optoelectronic arrangement according to claim 19, the method comprising:
providing the optoelectronic arrangement according to claim 1; and
picking the least one optoelectronic device such that a location of a break of the optoelectronic device from the first main surface begins at a position of the corner and continues from there in a direction of one side edge of the optoelectronic device.

32. A method for processing an optoelectronic device, the method comprising:
providing a growth substrate with a semiconductor layer stack comprising an active region, wherein the semiconductor layer stack is optionally mesa structured as to form a plurality of distinct optoelectronic devices, each of the plurality of distinct devices comprising a center;
generating a temporary carrier with a breakable anchoring structure having a first main surface to which a first one of the plurality of optoelectronic devices is attached to from a side opposite a main emission surface,
wherein the first main surface is displaced with respect to the center and comprises a corner facing the center with a smallest distance to it; and
forming the breakable anchoring structure with the first main surface comprising a non-rectangular shape that is symmetrical along an axis through the corner and the center.

33. The method according to claim 32,
wherein the breakable anchoring structure comprises a second main surface that is at least partially attached to a second one of the plurality of optoelectronic device, and
wherein the second main surface is displaced with respect to the center and comprises a corner facing a center of the second optoelectronic device with a smallest distance to it.

34. The method according to claim 32, wherein generating the temporary carrier comprises forming the breakable anchoring structure with the first main surface comprising a triangular shape with an angle at the corner of less than 60°.

35. The method according to claim 32, wherein generating the temporary carrier comprises forming an n-pointed star with prongs forming respective main surfaces therefrom.
